(19) United States
(12) Patent Application Publication
(10) Pub. No.: US 2026/0190559 A1
(43) Pub. Date: Jul. 2, 2026

(54) LIGHT-EMITTING DEVICE

(71) Applicant: NICHIA CORPORATION, Anan-shi (JP)

(72) Inventor: Takahito MIKI, Tokushima-shi (JP)

(73) Assignee: NICHIA CORPORATION, Anan-shi (JP)

(21) Appl. No.: 19/428,264

(22) Filed: Dec. 21, 2025

(30) Foreign Application Priority Data
Dec. 27, 2024 (JP) 2024-232066

(51) Int. Cl. H10H 20/858; H10H 20/831; H10H 20/851; H10H 20/854; H10H 20/856; H10H 20/857

(52) U.S. Cl. CPC H10H 20/8585; H10H 20/831; H10H 20/8512; H10H 20/854; H10H 20/856; H10H 20/857

(57) ABSTRACT

A light-emitting device includes: first and second electroconductive members spaced apart; a light-emitting element having a rectangular shape in top view and including a semiconductor layered body, a first electrode, and a second electrode; a first bonding member bonding the first electroconductive member and the first electrode; and a second bonding member bonding the second electroconductive member and the second electrode. The upper surface of the first electroconductive member includes a first flat portion and a first recessed portion in a vicinity of the first electrode and depressed from the first flat portion. The first recessed portion includes a first portion including a portion overlapping an outer periphery of the first electrode, and a second portion not overlapping the outer periphery. A portion of the first bonding member is in a first exposed region between the second portion and the first corner portion and exposed from the light-emitting element.

### CROSS-REFERENCE TO RELATED APPLICATIONS

The present application claims priority under 35 U.S.C. § 119 to Japanese Patent Application No. 2024-232066, filed Dec. 27, 2024. The contents of this application are incorporated herein by reference in their entirety.

### BACKGROUND

### 1. Field of the Invention

The present disclosure relates to a light-emitting device.

### 2. Description of Related Art

Japanese Patent No. 6776800 describes an electronic device having a structure in which an electronic component is mounted with an electroconductive bonding layer located therebetween, the electronic device including a supporting member having a mounting surface joined to the electroconductive bonding layer and a sealing surface that is provided outside the mounting surface to surround the mounting surface and has a rough surface formed of a plurality of laser irradiation traces.

### SUMMARY

The present disclosure advantageously provides embodiments of a light-emitting device that can enable improvement of heat dissipation performance and disposition of a light-emitting element at an intended position.

A light-emitting device according to one embodiment of the present disclosure includes: a first electroconductive member; a second electroconductive member spaced apart from the first electroconductive member; a light-emitting element having a rectangular shape in a top view, the light-emitting element comprising: a semiconductor layered body, a first electrode disposed between a lower surface of the semiconductor layered body and an upper surface of the first electroconductive member, and a second electrode disposed between the lower surface of the semiconductor layered body and an upper surface of the second electroconductive member; a first bonding member bonding the first electroconductive member and the first electrode together; and a second bonding member bonding the second electroconductive member and the second electrode together. The upper surface of the first electroconductive member includes: a first flat portion, and a first recessed portion located in at least a portion of vicinity of the first electrode in the top view and depressed from the first flat portion of the first electroconductive member toward a lower surface of the first electroconductive member. The first recessed portion includes, in the top view, a first portion including a portion with a boundary overlapping an outer periphery of the first electrode, and a second portion not overlapping the outer periphery of the first electrode. The second portion is spaced apart from at least one first corner portion of corner portions of the light-emitting element, the at least one first corner portion at least partly overlapping the first electroconductive member in the top view. A portion of the first bonding member is located in a first exposed region of the first flat portion, the first exposed region being located between the second portion and the first corner portion of the light-emitting element and exposed from the light-emitting element in the top view.

An embodiment of the present disclosure can enable improvement of heat dissipation performance and disposition of a light-emitting element at an intended position.

### BRIEF DESCRIPTION OF THE DRAWINGS

FIG. 1 is a schematic top view of a light-emitting device according to an embodiment.

FIG. 2 is a schematic top view of a portion of the light-emitting device according to the embodiment except a light-transmissive member.

FIG. 3A is a schematic top view of a first electroconductive member, a second electroconductive member, and a protective element included in the light-emitting device according to the embodiment.

FIG. 3B is a schematic top view of the first electroconductive member, the second electroconductive member, and the protective element included in the light-emitting device according to the embodiment.

FIG. 4 is a schematic cross-sectional view of the light-emitting device taken along the line IV-IV of FIG. 1.

FIG. 5 is a schematic partial top view of a portion of the first electroconductive member in the region V of FIG. 3B.

FIG. 6 is a schematic partial cross-sectional view of a portion of the first electroconductive member taken along the line VI-VI of FIG. 3A.

FIG. 7 is a schematic partial cross-sectional view of a portion of the light-emitting device taken along the line VII-VII of FIG. 1.

### DETAILED DESCRIPTION OF EMBODIMENTS

A light-emitting device according to an embodiment of the present disclosure will be described in detail below referring to the drawings. The modes to be described below are intended as examples of the light-emitting device to give concrete form to the technical idea of the embodiment and are not limited to the description below. Unless specifically stated otherwise, descriptions of the sizes, materials, shapes, and relative positions of constituent units in the embodiment described below are not intended to limit the scope of the present disclosure to those descriptions, but are rather merely examples for description. Sizes or positional relationships of members illustrated in each drawing may be exaggerated in order to clarify the descriptions. Furthermore, in the descriptions below, the same name or the same reference numeral represents the same member or a similar material, and its duplicative description will be omitted as appropriate. Cross-sectional end views showing only cut surfaces of members may be used as cross-sectional views.

In the drawings below, the X-axis, the Y-axis, and the Z-axis indicate directions in some cases. The X-axis, the Y-axis, and the Z-axis are directions orthogonal to one another. The direction of the arrow in the X-axis direction is denoted as the +X side, and the opposite direction is denoted as the −X side. The direction of the arrow in the Y-axis direction is denoted as the +Y side, and the opposite direction is denoted as the −Y side. The direction of the arrow in the Z-axis direction is denoted as the upper side or the +Z side, and the opposite direction is denoted as the lower side or the −Z side.

A top view among the terms of the embodiment means a view of an object from the +Z side. The above definitions do not limit the orientation of the light-emitting device during use, and any orientation of the light-emitting device is possible. In the embodiment, the surface on the +Z side (that is, the surface of an object viewed from the +Z side) is referred to as an “upper surface,” and the surface on the −Z side (that is, the surface of an object viewed from the −Z side) is referred to as a “lower surface.” In the embodiment below, the term “parallel” involves the case in which an inclination within the range of ±5° between two straight lines, surfaces, or the like exists.

In the present disclosure, a rectangular shape is a four-sided polygon (quadrilateral) with four right angles (90 degrees) and opposite sides that are equal in length and parallel (i.e. an equiangular quadrilateral including a square shape and an oblong shape). In the present disclosure, unless specifically stated otherwise, a polygonal shape such as a rectangular shape with beveled corners or the like of the polygonal shape is also referred to as a polygonal shape. Likewise, not only shapes with such modification at corners (that is, the ends of sides) but also shapes with modifications at intermediate portions of sides of the shapes are also referred to as polygonal shapes. That is, shapes based on polygonal shapes with partial modification are also interpreted as “polygonal shapes” in the present disclosure. In the present disclosure, the term “inward” or “inner” refers to a side closer to the center of the light-emitting device in a top view, and the term “outward” or “outer” refers to a side away from the center of the light-emitting device in a top view.

The term “cover” includes not only being in direct contact, but rather also includes indirect covering, such as covering via another member disposed therebetween. The term “dispose” includes not only disposition in direct contact but also includes indirect disposition, such as disposition via another member therebetween.

### Embodiment

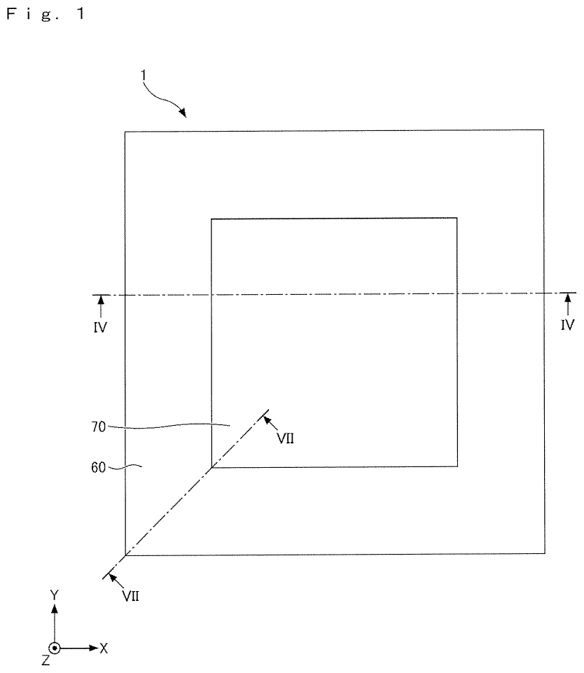

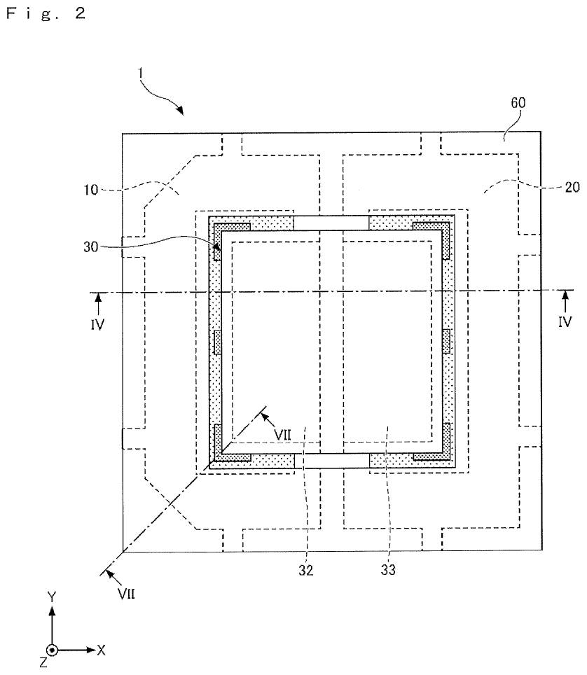

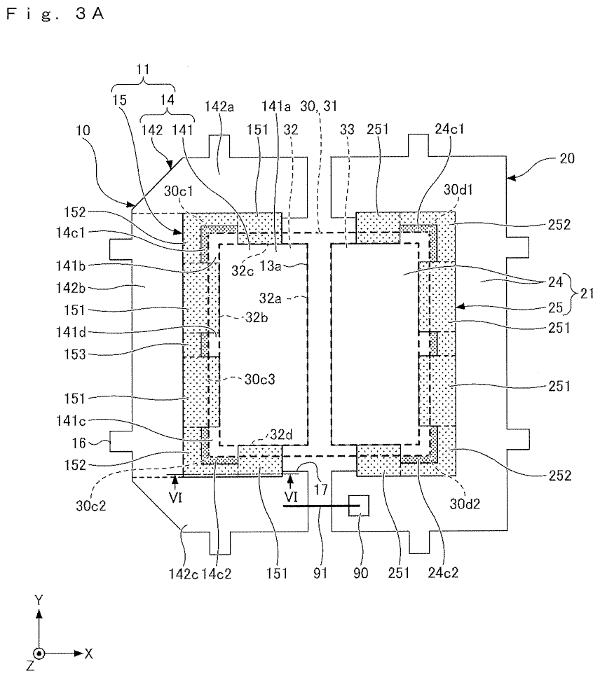

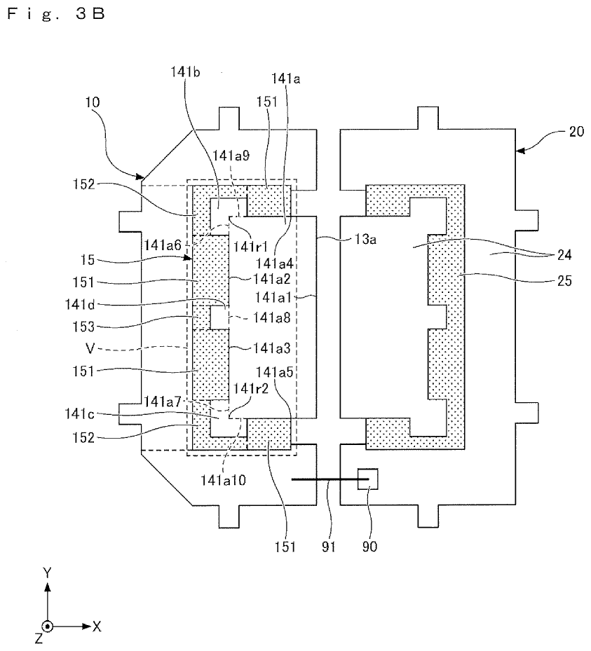

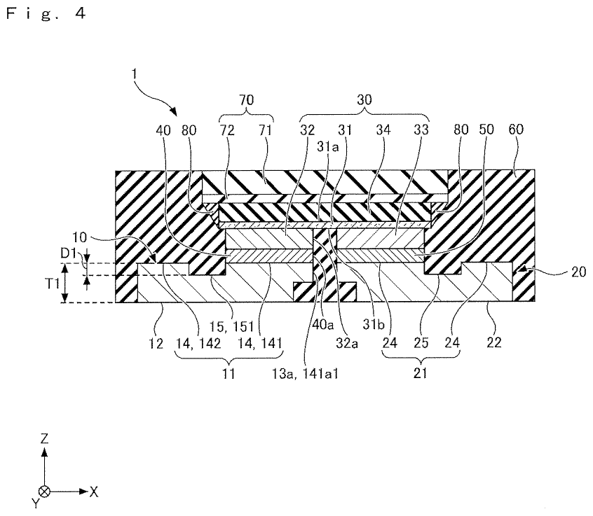

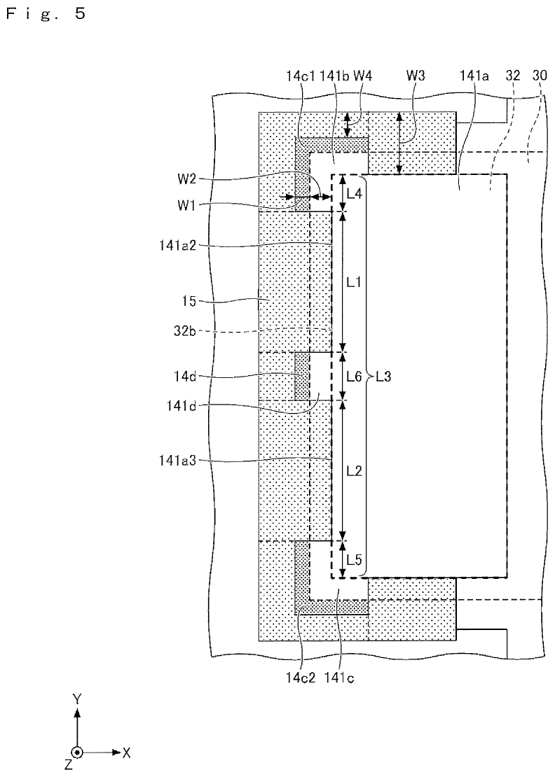

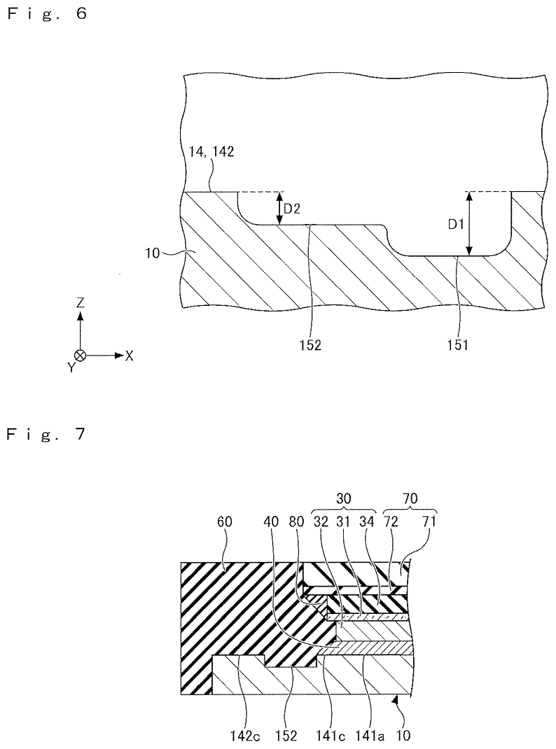

An example of the structure of a light-emitting device 1 according to an embodiment will be described referring to FIGS. 1 to 7. FIG. 1 is a schematic top view of the light-emitting device 1 according to the embodiment. FIG. 2 is a schematic top view of a portion of the light-emitting device 1 according to the embodiment except a light-transmissive member 70. FIGS. 3A and 3B are schematic top views of a first electroconductive member 10, a second electroconductive member 20, and a protective element 90 included in the light-emitting device 1 according to the embodiment. FIG. 4 is a schematic cross-sectional view of the light-emitting device 1 taken along the line IV-IV of FIG. 1. FIG. 5 is a schematic partial top view of a portion of the first electroconductive member 10 in the region V of FIG. 3B. FIG. 6 is a schematic partial cross-sectional view of a portion of the first electroconductive member 10 taken along the line VI-VI of FIG. 3A. FIG. 7 is a schematic partial cross-sectional view of a portion of the light-emitting device taken along the line VII-VII of FIG. 1. In FIGS. 3A and 5, the outer peripheries of a semiconductor layered body 31, a first electrode 32, and a second electrode 33 of a light-emitting element 30 included in the light-emitting device 1 are indicated by broken lines. In the example shown in FIGS. 3A and 5, the outer periphery of the semiconductor layered body 31 overlaps the outer periphery of the light-emitting element 30 in a top view.

As shown in FIGS. 1 to 4, the light-emitting device 1 includes the first electroconductive member 10, the second electroconductive member 20, the light-emitting element 30, a first bonding member 40, and a second bonding member 50. In the example shown in FIGS. 1 and 4, the light-emitting device 1 further includes a covering member 60, the light-transmissive member 70, a light-guiding member 80, and the protective element 90.

As shown in FIGS. 2 to 4, the first electroconductive member 10 and the second electroconductive member 20 are spaced apart from each other in the X-axis direction. The light-emitting element 30 is disposed across the first electroconductive member 10 and the second electroconductive member 20. The light-emitting element 30 includes the semiconductor layered body 31, the first electrode 32 disposed between a lower surface 31b of the semiconductor layered body 31 and an upper surface 11 of the first electroconductive member 10 in the Z-axis direction, and the second electrode 33 disposed between the lower surface 31b of the semiconductor layered body 31 and an upper surface 21 of the second electroconductive member 20 in the Z-axis direction. As shown in FIGS. 2 and 3A, the light-emitting element 30 has a rectangular shape in a top view. The first electrode 32 and the second electrode 33 have rectangular shapes in a top view.

As shown in FIGS. 3A and 3B, the upper surface 11 of the first electroconductive member 10 includes a first flat portion 14 and a first recessed portion 15. The first recessed portion 15 is depressed from the first flat portion 14 toward a lower surface 12 of the first electroconductive member 10 (see FIG. 4). The first recessed portion 15 is located in at least a portion of the vicinity of the first electrode 32 in a top view. In the example shown in FIG. 3A, in the vicinity of the first electrode 32, the first recessed portion 15 is located in a portion 32b on the −X side of the first electrode 32, a part of a portion 32c on the +Y side of the first electrode 32, and a part of a portion 32d on the −Y side of the first electrode 32. That is, the first recessed portion 15 is not located in a portion (a portion of the outer periphery of the first electrode 32 on the second electroconductive member 20 side) 32a on the +X side of the first electrode 32, the other part of the portion 32c on the +Y side of the first electrode 32, or the other part of the portion 32d on the −Y side of the first electrode 32.

As shown in FIG. 4, the first bonding member 40 bonds the first electroconductive member 10 to the first electrode 32. The second bonding member 50 bonds the second electroconductive member 20 to the second electrode 33. As shown in FIG. 7, the first bonding member 40 includes a portion located outward of the light-emitting element 30. As with the first bonding member 40, the second bonding member 50 also includes a portion located outward of the light-emitting element 30.

As shown in FIG. 3A, the first recessed portion 15 includes first portions 151 and second portions 152. The first portions 151 include portions with a boundary overlapping the outer periphery of the first electrode 32 in a top view. On the other hand, the second portions 152 do not overlap the outer periphery of the first electrode 32 in a top view and are spaced apart from first corner portions 30c1 and 30c2 overlapping the first electroconductive member 10 in a top view among the corner portions of the light-emitting element 30. Portions of the first bonding member 40 are located in first exposed regions 14c1 and 14c2 of the first flat portion 14 located between the second portions 152 and the first corner portions 30c1 and 30c2 of the light-emitting element 30 and exposed from the light-emitting element 30 in a top view. The first corner portions 30c1 and 30c2 of the light-emitting element 30 refer to intersection points of sides of the outer shape of the light-emitting element 30 in the region in which the light-emitting element 30 overlaps the first electroconductive member 10 of in a top view.

In the case in which a melting material is used for the first bonding member 40 and the second bonding member 50, the light-emitting element 30 is disposed on the first electroconductive member 10 and the second electroconductive member 20 via the first bonding member 40 and the second bonding member 50, and the first bonding member 40 and the second bonding member 50 are melted by heating and then cooled. The light-emitting element 30 is thus bonded to the first electroconductive member 10 and the second electroconductive member 20 via the first bonding member 40 and the second bonding member 50.

In the light-emitting device 1, with the first portions 151 of the first recessed portion 15, the first bonding member 40 melted in the bonding of the light-emitting element 30 can be less likely to spread into the first recessed portion 15 from the region of the first flat portion 14 overlapping the first electrode 32 in a top view. The spread of the first bonding member 40 can be thus reduced, which allows for reducing the possibility of occurrence of misalignment of the light-emitting element 30 from an intended position associated with the spread of the first bonding member 40. Further, portions of the first bonding member 40 are located in the first exposed regions 14c1 and 14c2 in the light-emitting device 1, so that the contact area between the first electroconductive member 10 and the first bonding member 40 can be increased. The heat generated in the light-emitting element 30 can thus be efficiently dissipated toward the first electroconductive member 10 through the first bonding member 40. Accordingly, the heat dissipation performance of the light-emitting device 1 can be improved.

Each member constituting the light-emitting device 1 will be described below.

### First Electroconductive Member 10 and Second Electroconductive Member 20

Each of the first electroconductive member 10 and the second electroconductive member 20 is an electroconductive member for supplying the light-emitting element 30 with power. In the example shown in FIGS. 1 to 4, each of the first electroconductive member 10 and the second electroconductive member 20 is a plate-shaped member patterned into a predetermined shape. In the example shown in FIGS. 1 to 4, the light-emitting device 1 includes two electroconductive members: the first electroconductive member 10 and the second electroconductive member 20. The number of electroconductive members included in the light-emitting device 1 can be three or more. In the example shown in FIGS. 3A, 3B, and 4, the first electroconductive member 10 is disposed on the −X side, and the second electroconductive member 20 is disposed on the +X side, but the positions of the first electroconductive member 10 and the second electroconductive member 20 in the X-axis direction can be reversed.

Each of the first electroconductive member 10 and the second electroconductive member 20 can include a base member and a plating layer provided on a surface of the base member. Examples of a material constituting the base member include copper (Cu), aluminum (Al), silver (Ag), gold (Au), zinc (Zn), chromium (Cr), tungsten (W), cobalt (Co), nickel (Ni), rhodium (Rh), ruthenium (Ru), and alloys of these metals. The base member can also contain a nonmetal such as silicon (Si) and phosphorus (P) as a trace element. The base member can have a single-layer structure formed of any of these metals and alloys or can have a multilayer structure.

The plating layer is preferably made of a material having a reflectance higher than the reflectance of the base member. Examples of a material constituting the plating layer include Ni, Ag, Au, platinum (Pt), palladium (Pd), Al, W, molybdenum (Mo), Ru, and Rh. The plating layer can have a single-layer structure formed of any of these metals or can have a multilayer structure. Examples of the multilayer plating layer include Ni/Pd/Au (that is, a plating layer in which Ni, Pd, and Au are layered in this order from the base member side), Ni/Pt/Au (that is, a plating layer in which Ni, Pt, and Au are layered in this order from the base member side), and Ni/Au/Ag (that is, a plating layer in which Ni, Au, and Ag are layered in this order from the base member side).

As shown in FIGS. 3A, 3B, and 4, the first electroconductive member 10 has the upper surface 11, the lower surface 12 opposite to the upper surface 11 in the Z-axis direction, and a plurality of lateral surfaces located between the upper surface 11 and the lower surface 12 in the Z-axis direction. The upper surface 11 of the first electroconductive member 10 includes the first flat portion 14 and the first recessed portion 15. The entire first flat portion 14 is a flat surface parallel to the X-axis direction and the Y-axis direction. The above description is not limiting, and the entire first flat portion 14 can be a rough surface. It is also possible that part of the first flat portion 14 is a flat surface and another part of the first flat portion 14 is a rough surface. In the case in which the first flat portion 14 includes a rough surface, the surface roughness of the first flat portion 14 is smaller than the maximum distance (depth) of the first recessed portion 15 in the Z-axis direction.

### (First Flat Portion 14)

In the example shown in FIGS. 3A and 3B, the first flat portion 14 includes a first region 141 and a second region 142. The first region 141 is a region of the first flat portion 14 located inward of the second region 142 in a top view.

In the example shown in FIGS. 3A and 3B, the first region 141 includes an inner region 141a, a first outer region 141b, a second outer region 141c, and a third outer region 141d. The configuration of the first region 141 is not limited to the example shown in FIGS. 3A and 3B. For example, the first region 141 does not necessarily include the third outer region 141d while including the inner region 141a, the first outer region 141b, and the second outer region 141c. The first region 141 can also include another outer region continuous with the inner region 141a.

The inner region 141a is located on the second electroconductive member 20 side with respect to the first outer region 141b, the second outer region 141c, and the third outer region 141d. The outer periphery of the inner region 141a coincides with the outer periphery of the first electrode 32 in a top view. In the example shown in FIGS. 3A and 3B, the inner region 141a has a rectangular shape in a top view. That is, as shown in FIG. 3B, the outer periphery of the inner region 141a in a top view is defined by a first side 141a1, a second side 141a2, a third side 141a3, a fourth side 141a4, and a fifth side 141a5, a virtual first extension 141a6 of the second side 141a2 on the +Y side, a virtual second extension 141a7 of the third side 141a3 on the −Y side, a virtual third extension 141a8 between the second side 141a2 and the third side 141a3 in the Y-axis direction, a virtual fourth extension 141a9 of the fourth side 141a4 on the −X side, and a virtual fifth extension 141a10 of the fifth side 141a5 on the −X side, which will be described below. The intersection point of the first extension 141a6 and the fourth extension 141a9 is hereinafter referred to as an “intersection point 141r1.” The intersection point of the second extension 141a7 and the fifth extension 141a10 is hereinafter referred to as an “intersection point 141r2.”

As shown in FIG. 3B, the inner region 141a has a plurality of sides. Among the sides of the inner region 141a, the side on the second electroconductive member 20 side is the first side 141a1. Among the sides of the inner region 141a, the sides opposite to the first side 141a1 in the X-axis direction are the second side 141a2 and the third side 141a3. Among the sides of the inner region 141a, the side located between the first side 141a1 and the second side 141a2 is the fourth side 141a4. Among the sides of the inner region 141a, the side between the first side 141a1 and the third side 141a3 is the fifth side 141a5.

In the example shown in FIG. 3B, the first side 141a1 of the inner region 141a overlaps a portion 13a (end of the first electroconductive member 10 on the +X side, hereinafter referred to as a “portion 13a of the first electroconductive member 10” in some cases) of the outer periphery of the first electroconductive member 10 on the second electroconductive member 20 side in a top view. The first side 141a1 of the inner region 141a also overlaps the portion 32a (hereinafter referred to as the “portion 32a of the first electrode 32” in some cases) of the outer periphery of the first electrode 32 on the second electroconductive member 20 side in a top view. Accordingly, the portion 32a of the first electrode 32 and the inner region 141a overlap the portion 13a of the first electroconductive member 10 in a top view. The above description is not limiting, and the portion 32a of the first electrode 32 and the inner region 141a do not necessarily overlap the portion 13a of the first electroconductive member 10 in a top view. For example, the portion 32a of the first electrode 32 and the inner region 141a can be located on the −X side of the portion 13a of the first electroconductive member 10 in a top view. In this case, the region between the portion 32a of the first electrode 32 (or the inner region 141a) and the portion 13a of the first electroconductive member 10 can be constituted of the first flat portion 14 and/or the first recessed portion 15. In the case in which the region between the portion 32a of the first electrode 32 (or the inner region 141a) and the portion 13a of the first electroconductive member 10 is constituted of the first recessed portion 15, the first recessed portion 15 can have an annular shape surrounding the first electrode 32.

Further, in the example shown in FIG. 4, an inner end 40a of the first bonding member 40 overlaps the portion 32a of the first electrode 32 in the Z-axis direction. That is, the inner end 40a of the first bonding member 40 overlaps the portion 13a of the first electroconductive member 10. With this structure, in bonding the light-emitting element 30, due to the surface tension at the inner end 40a of the first bonding member 40 the first bonding member 40 can be less likely to flow over the lateral surface of the first electroconductive member 10 facing the second electroconductive member 20. Accordingly, the possibility of occurrence of misalignment of the light-emitting element 30 from an intended position in the X-axis direction can be reduced.

As shown in FIG. 5, in a top view, the sum of a length L1 of overlap between the second side 141a2 of the inner region 141a and the first portion 151 and a length L2 of overlap between the third side 141a3 and the first portion 151 is preferably equal to or more than 0.4 times and equal to or less than 0.7 times a length L3 of the portion 32b (that is, the portion of the outer periphery of the first electrode 32 opposite to the second electroconductive member 20) of the first electrode 32 on the −X side. When the sum of the length L1 and the length L2 is equal to or more than 0.4 times the length L3, the region in which the possibility of spread of the first bonding member 40 from the first flat portion 14 into the first recessed portion 15 can be reduced at the time of bonding the light-emitting element 30 increases. Accordingly, the possibility of misalignment of the light-emitting element 30 from an intended position associated with the spread of the first bonding member 40 can be reduced. On the other hand, when the sum of the length L1 and the length L2 is equal to or more than 0.7 times the length L3, the first exposed regions 14c1 and 14c2 and a second exposed region 14d become larger. That is, the total length of lengths L4, L5, and L6 shown in FIG. 5 increases. The first bonding member 40 disposed in the first exposed regions 14c1 and 14c2 and the second exposed region 14d can thus be increased. Accordingly, the contact area between the first electroconductive member 10 and the first bonding member 40 increases, so that the heat dissipation performance of the light-emitting device 1 can be improved. In the case in which the first region 141 does not include the third outer region 141d, the sum of the length L1 and the length L2 is preferably equal to or more than 0.5 times and equal to or less than 0.8 times the length L3. With this structure, misalignment of the light-emitting element 30 from an intended position can be less likely to occur, and the heat dissipation performance of the light-emitting device 1 can be improved. In FIG. 5, the first exposed regions 14c1 and 14c2 and the second exposed region 14d are indicated by a dense dot pattern, and the first recessed portion 15 is indicated by a sparse dot pattern.

In the example shown in FIGS. 3A and 3B, the outer periphery of the inner region 141a coincides with the outer periphery of the first electrode 32 in a top view, and the inner region 141a has the same size as the first electrode 32. The inner region 141a can be smaller than the first electrode 32 in a top view. In this case, for example, a portion (portion 32a on the +X side) of the first electrode 32 overlaps the inner region 141a, and another portion (portion 32b on the −X side) of the first electrode 32 overlaps the first recessed portion 15 in a top view.

Each of the first outer region 141b, the second outer region 141c, and the third outer region 141d is continuous with the outer periphery of the inner region 141a and extends outward of the inner region 141a.

As shown in FIG. 3B, the first outer region 141b can be in contact with the intersection point 141r1.

As shown in FIG. 3A, the first outer region 141b includes the first exposed region 14c1. In FIG. 3A, the first exposed region 14c1 is indicated by a dense dot pattern. In the example shown in FIG. 3A, the first exposed region 14c1 includes a portion of the first outer region 141b extending in the X-axis direction in the end portion on the +Y side and a portion of the first outer region 141b extending in the Y-axis direction in the end portion on the −X side. A portion of the first bonding member 40 is located on the portion of the first exposed region 14c1 extending in the X-axis direction and/or the portion extending in the Y-axis direction. With the portion of the first bonding member 40 located on the portion of the first exposed region 14c1 extending in the X-axis direction and the portion extending in the Y-axis direction, the heat dissipation performance of the light-emitting device 1 can be further improved. Also, with the first bonding member 40 located in the first exposed region 14c1, it can be presumed that the first bonding member 40 exists in a wide region of the first electrode 32 (specifically exists to the outer periphery of the first electrode 32). The fact that the first bonding member 40 is disposed in the first exposed region 14c1 can be confirmed by, for example, visual observation from the upper side. Accordingly, the bonding quality of the light-emitting element 30 can be determined by simple means such as visual observation.

The first exposed region 14c1 overlaps the first corner portion 30c1 of the light-emitting element 30 in a top view. As the first exposed region 14c1 overlaps the first corner portion 30c1 of the light-emitting element 30 in a top view, the first bonding member 40 spreads over the first exposed region 14c1 and is disposed outward of the outer periphery of the first electrode 32.

As shown in FIG. 5, a width W1 of the first exposed region 14c1 is preferably equal to or more than 0.5 times and equal to or less than 0.75 times a distance W2 between the outer periphery of the light-emitting element 30 and the outer periphery of the first electrode 32 in a top view. When the width W1 of the first exposed region 14c1 is equal to or more than 0.5 times the distance W2 between the outer periphery of the light-emitting element 30 and the outer periphery of the first electrode 32, confirmation of spread of the first bonding member 40 outward of the outer periphery of the light-emitting element 30 in a top view by visual observation or the like is facilitated. On the other hand, when the width W1 of the first exposed region 14c1 is equal to or less than 0.75 times the distance W2 between the outer periphery of the light-emitting element 30 and the outer periphery of the first electrode 32, the first bonding member 40 can be less likely to excessively spread over the first outer region 141b when the light-emitting element 30 is bonded. Accordingly, the possibility of occurrence of an inclination of the light-emitting element 30 with respect to the Z-axis direction can be reduced. The “width W1 of the first exposed region 14c1” means the minimum width of the first exposed region 14c1. The “distance W2 between the outer periphery of the light-emitting element 30 and the outer periphery of the first electrode 32” means the minimum distance between the outer periphery of the light-emitting element 30 and the outer periphery of the first electrode 32.

As shown in FIG. 3B, the second outer region 141c can be in contact with the intersection point 141r2. As shown in FIG. 3A, the second outer region 141c overlaps the first corner portion 30c2 of the light-emitting element 30 in a top view. The second outer region 141c can further include the first exposed region 14c2. In FIG. 3A, the first exposed region 14c2 is indicated by a dense dot pattern. The other part of the configuration of the second outer region 141c is the same as the configuration of the first outer region 141b. Description of the other part of the configuration of the second outer region 141c is thus omitted.

The third outer region 141d is spaced apart from each of the first outer region 141b and the second outer region 141c and located between the first outer region 141b and the second outer region 141c in the Y-axis direction. The third outer region 141d extends on the −X side with respect to the second side 141a2 of the inner region 141a.

The third outer region 141d can include the second exposed region 14d located outward of the outer periphery of the light-emitting element 30 and exposed from the light-emitting element 30 in a top view. As the first bonding member 40 is disposed in the second exposed region 14d, the heat dissipation performance of the light-emitting device 1 can be improved. In FIG. 3A, the second exposed region 14d is indicated by a dense dot pattern.

In the example shown in FIGS. 3A and 3B, the area of the second exposed region 14d is smaller than the area of each of the first exposed regions 14c1 and 14c2. The area of the second exposed region 14d can be equal to or larger than the area of each of the first exposed region 14c1 and 14c2.

The second region 142 is a region of the first flat portion 14 located outward of the first region 141. In the example shown in FIG. 3A, the second region 142 includes a portion 142a that is located on the +Y side with respect to the first region 141 and extends in the X-axis direction, a portion 142b that is located on the −X side with respect to the first region 141 and extends in the Y-axis direction, and a portion 142c that is located on the −Y side with respect to the first region 141 and extends in the X-axis direction. The portion 142a is continuous with the end of the portion 142b on the +Y side. The portion 142c is continuous with the end of the portion 142b on the −Y side.

### (First Recessed Portion 15)

As described referring to FIGS. 3A and 3B, the first recessed portion 15 is located in at least a portion of the vicinity of the first electrode 32 in a top view. The first region 141 and the second region 142 of the first flat portion 14 are spaced apart from each other by the first recessed portion 15, so that the possibility that the first bonding member 40 disposed in the first region 141 spreads over the second region 142 when the light-emitting element 30 is bonded can be reduced. The first bonding member 40 thus remains within the first region 141, so that the spread of the first bonding member 40 can be reduced. Accordingly, the possibility of misalignment of the light-emitting element 30 from an intended position associated with the spread of the first bonding member 40 can be reduced. The first bonding member 40 remains within the first region 141 to reduce the possibility of a reduction in the thickness of the first bonding member 40 associated with the spread of the first bonding member 40. Accordingly, the possibility of occurrence of an inclination of the light-emitting element 30 with respect to the Z-axis direction can be reduced. In FIG. 3A, the first recessed portion 15 is indicated by a sparse dot pattern.

The first recessed portion 15 includes the first portions 151 including portions overlapping the outer periphery of the first electrode 32 and the second portions 152 that do not overlap the outer periphery of the first electrode 32 and are spaced apart from the first corner portions 30c1 and 30c2 of the light-emitting element 30 in a top view. In a top view, the first portions 151 include portions overlapping the outer periphery of the first electrode 32 while the second portions 152 do not overlap the outer periphery of the first electrode 32, so that the region (the first outer region 141b and the second outer region 141c in the example shown in FIGS. 3A and 3B) extending outward of the outer periphery of the first electrode 32 can be provided in the first flat portion 14. The second portions 152 are spaced apart from the first corner portions 30c1 and 30c2 of the light-emitting element 30, so that the regions (the first outer region 141b and the second outer region 141c in the example shown in FIGS. 3A and 3B) extending outward of the outer periphery of the first electrode 32 can include the first exposed regions 14c1 and 14c2 exposed from the light-emitting element 30.

As shown in FIG. 4, the maximum depth (depth D1 of the first portions 151 in the example shown in FIG. 4) of the first recessed portion 15 is preferably equal to or more than 0.25 times and equal to or less than 0.75 times a thickness T1 of the first electroconductive member 10 in a cross-sectional view. When the maximum depth of the first recessed portion 15 is equal to or more than 0.25 times the thickness T1 of the first electroconductive member 10, the strength of the first electroconductive member 10 can be secured. On the other hand, when the maximum depth of the first recessed portion 15 is equal to or less than 0.75 times the thickness T1 of the first electroconductive member 10, the first bonding member 40 can be less likely to spread from the first flat portion 14 into the first recessed portion 15 at the time of bonding the light-emitting element 30.

As shown in FIG. 6, the depth D1 of the first portions 151 is preferably larger than a depth D2 of the second portions 152 in a cross-sectional view. With this structure, the first bonding member 40 is less likely to spread over the second portions 152 at the time of bonding the light-emitting element 30. For example, the depth D2 of the second portions 152 is equal to or more than 0.5 times and equal to or less than 0.9 times the depth D1 of the first portions 151.

In the example shown in FIG. 5, a width W3 of the first portions 151 in the Y-axis direction is larger than a width W4 of the second portions 152 in the Y-axis direction. The contact area between the first electroconductive member 10 and the covering member 60 described below can thus be increased compared with the case in which the width W3 of the first portions 151 in the Y-axis direction is equal to the width W4 of the second portions 152 in the Y-axis direction. Accordingly, the adhesion between the first electroconductive member 10 and the covering member 60 can be improved. The “width W3 of the first portions 151 in the Y-axis direction” means the minimum width of the first portions 151 in the Y-axis direction. The “width W4 of the second portions 152 in the Y-axis direction” means the minimum width of the second portions 152 in the Y-axis direction.

The first recessed portion 15 can further include a third portion 153 as shown in FIG. 3A. In the example shown in FIG. 3A, the third portion 153 is spaced apart from a portion 30c3 of the outer periphery of the light-emitting element 30 located between the two first corner portions 30c1 and 30c2. As the third portion 153 is spaced apart from the portion 30c3 of the outer periphery of the light-emitting element 30, the region (second exposed region 14d) extending outward of the outer periphery of the light-emitting element 30 can be further provided in the first flat portion 14. A portion of the first bonding member 40 can be disposed in the second exposed region 14d. The heat dissipation performance of the light-emitting device 1 can thus be improved.

### (Projection 16 and Penetrating Portion 17)

In the example shown in FIGS. 3A and 3B, the first electroconductive member 10 further includes a projection 16 and a penetrating portion 17. The projection 16 is a portion used for connecting the first electroconductive member 10 before singulation to another electroconductive member. The projection 16 projects outward from the outer periphery of the second region 142 of the first flat portion 14.

The penetrating portion 17 is located on the +X side of the first recessed portion 15 and overlaps the outer periphery of the first electrode 32 in a top view. The penetrating portion 17 penetrates through the first electroconductive member 10 in the Z-axis direction, and a portion of lateral surfaces defining the penetrating portion 17 is open. That is, as shown in FIG. 3A, the +X side (second electroconductive member 20 side) of the penetrating portion 17 is open in a top view. The penetrating portion 17 of the first electroconductive member 10 enables reduction of the possibility that the first bonding member 40 melted when the light-emitting element 30 is bonded spreads from the first region 141 of the first flat portion 14 over the penetrating portion 17 in a top view.

The second electroconductive member 20 is spaced apart from the first electroconductive member 10. As shown in FIG. 4, the second electroconductive member 20 has the upper surface 21, a lower surface 22, and a plurality of lateral surfaces located between the upper surface 21 and the lower surface 22 in the Z-axis direction. The upper surface 21 of the second electroconductive member 20 includes a second flat portion 24 and a second recessed portion 25. The second recessed portion 25 is located in at least a portion of the vicinity of the second electrode 33 in a top view. The second recessed portion 25 includes fourth portions 251 including portions with a boundary overlapping the outer periphery of the second electrode 33 and fifth portions 252 that do not overlap the outer periphery of the second electrode 33 in a top view. The fifth portions 252 are spaced apart from second corner portions 30d1 and 30d2 overlapping the second electroconductive member 20 in a top view among the corner portions of the light-emitting element 30. Portions of the second bonding member 50 are located in third exposed regions 24c1 and 24c2 of the second flat portion 24 located between the fifth portions 252 and the second corner portions 30d1 and 30d2 of the light-emitting element 30 and exposed from the light-emitting element 30 in a top view. The other part of the configuration of the second electroconductive member 20 is the same as in the first electroconductive member 10. Description of the other part of the configuration of the second electroconductive member 20 is thus omitted. In FIGS. 3A and 5, the third exposed regions 24c1 and 24c2 are indicated by a dense dot pattern. In FIG. 3A, the second recessed portion 25 is indicated by a sparse dot pattern.

### Light-Emitting Element 30

The light-emitting element 30 is a semiconductor element that is configured to emit light when voltage is applied. Examples of the light-emitting element 30 include a light emitting diode (LED) chip. The light-emitting element 30 has a rectangular shape in a top view.

In the example shown in FIG. 4, the light-emitting element 30 includes an element substrate 34 in addition to the semiconductor layered body 31, the first electrode 32, and the second electrode 33. The element substrate 34 is disposed on the semiconductor layered body 31. The element substrate 34 is light-transmissive. The term “light-transmissive” as used herein refers to, for example, the property that the transmittance of light emitted from the light-emitting element 30 is at least 60% or more, preferably 80% or more. Examples of a material constituting the element substrate 34 include sapphire, spinel, glass, aluminum nitride, and silicon carbide. The light-emitting element 30 does not necessarily include the element substrate 34.

As shown in FIG. 4, the semiconductor layered body 31 can have an upper surface 31a, the lower surface 31b, and a plurality of lateral surfaces located between the upper surface 31a and the lower surface 31b in the Z-axis direction.

The semiconductor layered body 31 includes a first semiconductor layer, a light-emitting layer, and a second semiconductor layer. The first semiconductor layer, the light-emitting layer, and the second semiconductor layer are layered in the Z-axis direction. The first semiconductor layer and the second semiconductor layer are of different conduction types. For example, in the case in which the first semiconductor layer is an n-type semiconductor layer, the second semiconductor layer is a p-type semiconductor layer. In the case in which the first semiconductor layer is a p-type semiconductor layer, the second semiconductor layer is an n-type semiconductor layer. One of the first semiconductor layer and the second semiconductor layer is electrically connected to the first electrode 32. The other one of the first semiconductor layer and the second semiconductor layer is electrically connected to the second electrode 33. The light-emitting layer can have a single quantum well (SQW) structure or a multi quantum well (MQW) structure including a plurality of well layers.

For example, each of the first semiconductor layer, the light-emitting layer, and the second semiconductor layer is a semiconductor layer made of a nitride semiconductor. The nitride semiconductor includes semiconductors of any compositions in which composition ratios x and y in the chemical formula InₓAl_{y}Ga_{1-x-y}N (0≤x, 0≤y, and x+y≤1) vary in corresponding ranges. The peak emission wavelength of the light-emitting layer can be appropriately selected according to the purpose. For example, the light-emitting layer is configured to be able to emit visible light or ultraviolet light.

In the case in which a structure including the first semiconductor layer, the light-emitting layer, and the second semiconductor layer is regarded as one layered body, the semiconductor layered body 31 can include a plurality of layered bodies. In this case, for example, the layered bodies can be layered in order in the Z-axis direction. The light-emitting layers of the respective layered bodies can include well layers configured to emit different peak emission wavelengths or can include well layers configured to emit the same peak emission wavelength.

The combination of peak emission wavelengths of a plurality of layered bodies can be appropriately selected. In the case in which the semiconductor layered body 31 includes two layered bodies, examples of the combination of light emitted from the respective light-emitting layers of the layered bodies include blue light and blue light, green light and green light, red light and red light, ultraviolet light and ultraviolet light, ultraviolet light and blue light, blue light and green light, blue light and red light, and green light and red light. In the case in which the semiconductor layered body 31 includes three layered bodies, examples of the combination of light emitted from the respective light-emitting layers of the layered bodies include blue light, green light, and red light.

As shown in FIG. 4, the first electrode 32 and the second electrode 33 are spaced apart from each other in the X-axis direction. In the Z-axis direction, the first electrode 32 is disposed between the lower surface 31b of the semiconductor layered body 31 and the first flat portion 14 (first region 141) of the upper surface 11 of the first electroconductive member 10. In the Z-axis direction, the second electrode 33 is disposed between the lower surface 31b of the semiconductor layered body 31 and the second flat portion 24 of the upper surface 21 of the second electroconductive member 20.

Examples of a material constituting each of the first electrode 32 and the second electrode 33 include metals such as Au, Ag, Cu, Al, Ni, Rh, Ti, Pt, Pd, Mo, Cr, and W and alloys containing any of these metals. Each of the first electrode 32 and the second electrode 33 can have a single-layer structure formed of any of these metals and alloys or can have a multilayer structure in which a plurality of layers formed of any of these metals and alloys are layered.

In the X-axis direction, the distance W2 between the outer periphery of the light-emitting element 30 and the outer periphery of the first electrode 32 is preferably equal to or more than 0.01 times and equal to or less than 0.1 times the width of the light-emitting element 30. When the distance W2 between the outer periphery of the light-emitting element 30 and the outer periphery of the first electrode 32 is equal to or more than 0.01 times the width of the light-emitting element 30 in the X-axis direction, the possibility that the first bonding member 40 creeps up the lateral surfaces of the semiconductor layered body 31 of the light-emitting element 30 can be reduced when the first bonding member 40 spreads at the time of bonding the light-emitting element 30. The possibility of a short circuit of the light-emitting element 30 can thus be reduced. On the other hand, when the distance W2 between the outer periphery of the light-emitting element 30 and the outer periphery of the first electrode 32 is equal to or less than 0.1 times the light-emitting element 30 in the X-axis direction, the first bonding member 40 can reach the first exposed region 14c1 when the first bonding member 40 spreads at the time of bonding the light-emitting element 30.

### First Bonding Member 40 and Second Bonding Member 50

As shown in FIG. 4, in the Z-axis direction, the first bonding member 40 is disposed between the first flat portion 14 (first region 141) of the upper surface 11 of the first electroconductive member 10 and the lower surface of the first electrode 32. In the Z-axis direction, the second bonding member 50 is disposed between the second flat portion 24 of the upper surface 21 of the second electroconductive member 20 and the lower surface of the second electrode 33.

Examples of a material constituting each of the first bonding member 40 and the second bonding member 50 include a melting material. Examples of the melting material include alloys such as Au—Sn, Sn—Ag—Cu, Sn—Cu, Sn—Sb, Sn—Bi, Sn—In, Sn—Pb, and Ni—Sn.

### Covering Member 60

The covering member 60 is light-reflective. The covering member 60 covers the first electroconductive member 10, the second electroconductive member 20, the light-emitting element 30, the first bonding member 40, and the second bonding member 50 such that the lower surface 12 of the first electroconductive member 10 and the lower surface 22 of the second electroconductive member 20 are exposed. As the lower surface 12 of the first electroconductive member 10 and the lower surface 22 of the second electroconductive member 20 are exposed from the covering member 60, dissipation of the heat generated in the light-emitting element 30 to the outside through the lower surfaces of the first electroconductive member 10 and the second electroconductive member 20 is facilitated. The covering member 60 also covers the first recessed portion 15 of the upper surface 11 of the first electroconductive member 10. The contact area between the first electroconductive member 10 and the covering member 60 is therefore increased as compared with the case in which the first electroconductive member 10 does not have the first recessed portion 15, so that the adhesion between the first electroconductive member 10 and the covering member 60 can be improved. Further, as the covering member 60 is disposed in the first recessed portion 15, the volume of the covering member 60 included in the light-emitting device 1 can be increased as compared with the case in which the first electroconductive member 10 does not have the first recessed portion 15, so that the light extraction efficiency of the light-emitting device 1 can be improved.

As shown in FIG. 4, the covering member 60 covers lateral surfaces of the light-emitting element 30. Accordingly, the light emitted from the lateral surfaces of the light-emitting element 30 can be reflected toward the upper surface of the light-emitting element 30, so that the light extraction efficiency of the light-emitting device 1 can be improved. A portion of the covering member 60 is disposed between the first electrode 32 and the second electrode 33 and between the first electroconductive member 10 and the second electroconductive member 20 in a cross-sectional view. Light emitted from the light-emitting element 30 downward can thus be inhibited from being absorbed by the first electroconductive member 10, the second electroconductive member 20, the first bonding member 40, and the second bonding member 50. Accordingly, the light extraction efficiency of the light-emitting device 1 can be improved.

The covering member 60 can have an insulating property. As shown in FIG. 4, the covering member 60 is disposed between the first electrode 32 and the second electrode 33 and between the first electroconductive member 10 and the second electroconductive member 20. The possibility of short circuits between the first electrode 32 and the second electrode 33 and between the first electroconductive member 10 and the second electroconductive member 20 can thus be reduced.

Examples of a material constituting the covering member 60 include thermosetting resins. Examples of the thermosetting resins include epoxy resins, modified epoxy resins, silicone resins, modified silicone resins, acrylate resins, polyester resins (such as unsaturated polyester resins), and urethane resins. The covering member 60 can further include light-reflective particles. Examples of the light-reflective particles include inorganic particles such as titanium oxide, silicon oxide, aluminum oxide, zirconium oxide, magnesium oxide, potassium titanate, barium titanate, zinc oxide, silicon nitride, aluminum nitride, boron nitride, calcium carbonate, calcium hydroxide, and calcium silicate.

### Light-Transmissive Member 70

The light-transmissive member 70 is a light-transmissive member that is disposed on the light-emitting element 30 and transmits light emitted from the light-emitting element 30 to the outside. The light-transmissive member 70 is covered with the covering member 60 such that the upper surface of the light-transmissive member 70 is exposed. Part of the light emitted from the light-emitting element 30, which passes through the lateral surfaces of the light-transmissive member 70, is reflected by the covering member 60 toward the upper surface of the light-transmissive member 70.

In the example shown in FIG. 4, the light-transmissive member 70 has a multilayer structure in which a light-transmissive layer 71 that is light-transmissive and a wavelength conversion layer 72 are layered. The wavelength conversion layer 72 is located on the −Z side of the light-transmissive layer 71.

Examples of a material constituting the light-transmissive layer 71 include inorganic materials such as glass, ceramic, and sapphire and organic materials such as a resin or a hybrid resin containing one or more of a silicone resin, a modified silicone resin, an epoxy resin, a modified epoxy resin, an acrylic resin, a phenolic resin, and a fluorocarbon resin.

For example, the wavelength conversion layer 72 includes a base material formed of a thermoplastic resin or a thermosetting resin and a wavelength conversion material contained in the base material. The wavelength conversion material is configured to perform wavelength Conversion of at least a portion of light coming from the light-emitting element 30. This configuration makes it easy to adjust the chromaticity of the light-emitting device 1. The wavelength conversion material contained in the wavelength conversion layer 72 can be of one type or a plurality of types. A phosphor can be used as the wavelength conversion material.

Examples of the phosphor include yttrium-aluminum-garnet based phosphors (such as Y₃(Al, Ga)₅O₁₂:Ce), lutetium-aluminum-garnet based phosphors (such as Lu₃(Al, Ga)₅O₁₂:Ce), terbium-aluminum-garnet based phosphors (such as Tb₃(Al, Ga)₅O₁₂:Ce), CCA based phosphors (such as Ca₁₀(PO₄)₆Cl₂:Eu), SAE based phosphors (such as Sr₄Al₁₄O₂₅:Eu), chlorosilicate based phosphors (such as Ca₈MgSi₄O₁₆Cl₂:Eu), nitride based phosphors such as β-SiAlON based phosphors (such as (Si, Al)₃(O, N)₄:Eu), α-SiAlON based phosphors (such as Ca(Si, Al)₁₂(O, N)₁₆:Eu), SLA based phosphors (such as SrLiAl₃N₄:Eu), CASN based phosphors (such as CaAlSiN₃:Eu), and SCASN based phosphors (such as (Sr, Ca)AlSiN₃:Eu), fluoride based phosphors such as KSF based phosphors (such as K₂SiF₆:Mn), KSAF based phosphors (such as K₂(Si, Al)F₆:Mn), and MGF based phosphors (such as 3.5MgO·0.5MgF₂·GeO₂:Mn), phosphors having the perovskite structure (such as CsPb(F, Cl, Br, I)₃), and quantum-dot phosphors (such as CdSe, InP, AgInS₂, and AgInSe₂).

The light-transmissive member 70 is not limited to the member having the multilayer structure in which the light-transmissive layer 71 and the wavelength conversion layer 72 are layered. For example, the light-transmissive member 70 can have a single-layer structure including a base material formed of the same material as the light-transmissive layer 71 and a wavelength conversion material contained in the base. The light-emitting device 1 is not limited to a device including the light-transmissive member 70 and does not necessarily include the light-transmissive member 70.

### Light-Guiding Member 80

The light-guiding member 80 is a member for bonding the light-emitting element 30 and the light-transmissive member 70 together. The light-guiding member 80 is disposed between the upper surface of the light-emitting element 30 and the lower surface of the light-transmissive member 70. As shown in FIG. 4, the light-guiding member 80 can further cover lateral surfaces of the semiconductor layered body 31. The light-guiding member 80 can thus guide the light emitted from the lateral surfaces of the light-emitting element 30 to the light-transmissive member 70. Accordingly, the light extraction efficiency of the light-emitting device 1 can be improved. The light-guiding member 80 does not necessarily cover the lateral surfaces of the semiconductor layered body 31.

In the example shown in FIG. 4, the light-guiding member 80 has such a triangular cross-sectional shape that becomes wider in the X-axis direction along the upper direction. That is, the outer surface of the light-guiding member 80 forms a straight line in a cross-sectional view. The outer surface of the light-guiding member 80 can form a curved line in a cross-sectional view.

For example, a resin material can be used for the light-guiding member 80. As the resin material, a resin material made of a resin or hybrid resin containing one or more of a silicone resin, a modified silicone resin, an epoxy resin, a modified epoxy resin, an acrylic resin, and a fluorocarbon resin can be used.

### Protective Element 90

The protective element 90 is connected in parallel to the light-emitting element 30. When an excessive voltage load is applied to the light-emitting element 30, the resistance of the parallel circuit including the protective element 90 decreases, thereby bypassing of an electric current and reducing the voltage applied between the first electrode 32 and the second electrode 33 of the light-emitting element 30. For example, the protective element 90 is a Zener diode. The protective element 90 is not limited to a Zener diode but can be another protective element such as a varistor.

In the example shown in FIGS. 3A and 3B, the protective element 90 is disposed on the upper surface 21 of the second electroconductive member 20. For example, the protective element 90 is electrically connected to the first electroconductive member 10 via a bonding wire 91. For example, the protective element 90 can be disposed on the upper surface 11 of the first electroconductive member 10 and electrically connected to the second electroconductive member 20 via the bonding wire 91. Alternatively, the protective element 90 can be disposed across the upper surface 11 of the first electroconductive member 10 and the upper surface 21 of the second electroconductive member 20.

The preferable embodiment has been described above in detail, but the above-described embodiment and the like are not limiting. Change or replacement in a wide range can be carried out in the embodiment and the like within the scope specified by the claims.

What is claimed is:

1. A light-emitting device comprising:
a first electroconductive member;
a second electroconductive member spaced apart from the first electroconductive member;
a light-emitting element having a rectangular shape in a top view, the light-emitting element comprising:
a semiconductor layered body,
a first electrode disposed between a lower surface of the semiconductor layered body and an upper surface of the first electroconductive member, and
a second electrode disposed between the lower surface of the semiconductor layered body and an upper surface of the second electroconductive member;
a first bonding member bonding the first electroconductive member and the first electrode together; and
a second bonding member bonding the second electroconductive member and the second electrode together, wherein
the upper surface of the first electroconductive member includes:
a first flat portion, and
a first recessed portion located in at least a portion of vicinity of the first electrode in the top view and depressed from the first flat portion of the first electroconductive member toward a lower surface of the first electroconductive member,
the first recessed portion includes, in the top view,
a first portion including a portion with a boundary overlapping an outer periphery of the first electrode, and
a second portion not overlapping the outer periphery of the first electrode,
the second portion is spaced apart from at least one first corner portion of corner portions of the light-emitting element, the at least one first corner portion at least partly overlapping the first electroconductive member in the top view, and
a portion of the first bonding member is located in a first exposed region of the first flat portion, the first exposed region being located between the second portion and the first corner portion of the light-emitting element and exposed from the light-emitting element in the top view.

2. The light-emitting device according to claim 1, wherein, in a cross-sectional view, a depth of the first portion is larger than a depth of the second portion.

3. The light-emitting device according to claim 1, wherein a portion of an outer periphery of the first electroconductive member on a second electroconductive member side overlaps a portion of the outer periphery of the first electrode on the second electroconductive member side in the top view.

4. The light-emitting device according to claim 1, further comprising a light-reflective covering member covering the first electroconductive member, the second electroconductive member, the light-emitting element, the first bonding member, and the second bonding member such that the lower surface of the first electroconductive member and a lower surface of the second electroconductive member are exposed.

5. The light-emitting device according to claim 1, wherein
the at least one first corner portion of the light-emitting element includes two first corner portions,
the first recessed portion includes a third portion spaced apart from a portion of an outer periphery of the light-emitting element located between the two first corner portions, and
in the top view, a portion of the first bonding member is located in a second exposed region of the first flat portion, the second exposed region being located between the third portion and the light-emitting element and exposed from the light-emitting element.

6. The light-emitting device according to claim 1, wherein
the upper surface of the second electroconductive member includes:
a second flat portion, and
a second recessed portion located in at least a portion of vicinity of the second electrode in the top view and depressed from the second flat portion of the second electroconductive member toward a lower surface of the second electroconductive member,
the second recessed portion includes:
a fourth portion including a portion with a boundary overlapping an outer periphery of the second electrode, and
a fifth portion not overlapping the outer periphery of the second electrode in the top view,
the fifth portion is spaced apart from a second corner portion of the corner portions of the light-emitting element, the second corner portion at least partly overlapping the second electroconductive member in the top view, and
a portion of the second bonding member is located in a third exposed region of the second flat portion, the third exposed region being located between the fifth portion and the second corner portion of the light-emitting element and exposed from the light-emitting element in the top view.

7. The light-emitting device according to claim 2, wherein a portion of an outer periphery of the first electroconductive member on a second electroconductive member side overlaps a portion of the outer periphery of the first electrode on the second electroconductive member side in the top view.

8. The light-emitting device according to claim 2, further comprising a light-reflective covering member covering the first electroconductive member, the second electroconductive member, the light-emitting element, the first bonding member, and the second bonding member such that the lower surface of the first electroconductive member and a lower surface of the second electroconductive member are exposed.

9. The light-emitting device according to claim 2, wherein
the at least one first corner portion of the light-emitting element includes two first corner portions,
the first recessed portion includes a third portion spaced apart from a portion of an outer periphery of the light-emitting element located between the two first corner portions, and
in the top view, a portion of the first bonding member is located in a second exposed region of the first flat portion, the second exposed region being located between the third portion and the light-emitting element and exposed from the light-emitting element.

10. The light-emitting device according to claim 2, wherein
the upper surface of the second electroconductive member includes:
a second flat portion, and
a second recessed portion located in at least a portion of vicinity of the second electrode in the top view and depressed from the second flat portion of the second electroconductive member toward a lower surface of the second electroconductive member,
the second recessed portion includes:
a fourth portion including a portion with a boundary overlapping an outer periphery of the second electrode, and
a fifth portion not overlapping the outer periphery of the second electrode in the top view,
the fifth portion is spaced apart from a second corner portion of the corner portions of the light-emitting element, the second corner portion at least partly overlapping the second electroconductive member in the top view, and
a portion of the second bonding member is located in a third exposed region of the second flat portion, the third exposed region being located between the fifth portion and the second corner portion of the light-emitting element and exposed from the light-emitting element in the top view.
